(19) United States
(12) Patent Application Publication
(10) Pub. No.: US 2004/0147116 A1
(43) Pub. Date: Jul. 29, 2004

(54) Novel method to reduce stress for copper CMP

(75) Inventors: Kei-Wei Chen, Yung-Ho City (TW); Ting-Chun Wang, Taoyuan (TW); Kuo-Hsiu Wei, Banchiau City (TW); Yu-Ku Lin, Hsin-Chu City (TW); Ying-Lang Wang, Lung-Jing Country (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/353,421

(22) Filed: Jan. 29, 2003

(51) Int. Cl. H01L 21/00; H01L 21/44

(52) U.S. Cl. 438/687; 438/692; 438/5

(57) ABSTRACT

A new method is provided for polishing, using methods of Chemical Mechanical Polishing, of copper surfaces, particularly where these surface are adjacent to the surface of a layer of barrier material comprising TaN. The invention provides for reducing the chemical force early in the polishing process by adding DIW during the early polishing phase and for additional control of the chemical force during the polishing process by controlling the pH of the slurry applied during polishing, especially for polishing the interface between interconnect copper and barrier material TaN.

### BACKGROUND OF THE INVENTION

(1) Field of the Invention

The invention relates to the fabrication of integrated circuit devices, and more particularly, to a method to improve the process of polishing copper surfaces.

(2) Description of the Prior Art

A significant aspect of the creation of semiconductor devices addresses the interconnection of these devices. For these interconnections, metals such as aluminum or their alloys have been used extensively in the past, in more recent developments copper is becoming the preferred material. Copper has of late been the material of choice in view of the more attractive performance characteristics of copper such as low cost and low resistivity. Copper however has a relatively large diffusion coefficient into surrounding dielectrics such as silicon dioxide and silicon. Copper that forms a conductive interconnect may diffuse into the surrounding dielectric, causing the dielectric to be conductive and decreasing the dielectric strength of the silicon dioxide layer. Copper interconnects are therefore preferably encapsulated by at least one diffusion barrier to prevent diffusion of the copper into the silicon dioxide layer. Silicon nitride is a diffusion barrier to copper, but the prior art teaches that the interconnects should not lie on a silicon nitride layer because it has a high dielectric constant compared with silicon dioxide. The high dielectric constant causes an undesired increase in capacitance between the interconnect and the substrate. Copper further has low adhesive strength to various insulating layers, while it has been proven inherently difficult to mask and etch a blanket copper layer into intricate circuit structures.

While copper has become important for the creation of multilevel interconnections, copper lines frequently show damage after CMP and clean. This in turn causes problems with planarization of subsequent layers that are deposited over the copper lines since these layers may now be deposited on a surface of poor planarity. Isolated copper lines or copper lines that are adjacent to open fields are susceptible to damage. Poor copper gap fill together with subsequent problems of etching and planarization are suspected as being the root causes for these damages. Where over-polish is required, the problem of damaged copper lines becomes even more severe.

The increasing need to form planar surfaces in semiconductor device fabrication has led to the development of a process technology known as Chemical Mechanical Planarization (CMP). In the CMP process, semiconductor substrates are rotated, face down, against a polishing pad in the presence of an abrasive slurry. Most commonly, the layer to be planarized is an electrical insulating layer overlaying active circuit devices. As the substrate is rotated against the polishing pad, the abrasive force grinds away the surface of the insulating layer. Additionally, chemical compounds within the slurry undergo a chemical reaction with the components of the insulating layer to enhance the rate of removal. By carefully selecting the chemical components of the slurry, the polishing process can be made more selective to one type of material than to another. For example, in the presence of potassium hydroxide, silicon dioxide is removed at a faster rate than silicon nitride. The ability to control the selectivity of a CMP process has led to its increased use in the fabrication of complex integrated circuits.

It has been observed that for copper CMP processes, recesses are induced by the interaction between copper and barrier material TaN in the interface between these materials. This effect is strongly dependent on the topography of the created interconnect lines such as the creation of long lines of copper interconnect traces. This interaction readily leads to failure of stacks of overlying vias, to increasing interconnect resistance and ultimately to concerns of device reliability. The invention addresses these concerns, specifically addressing the concern of the occurrence of recesses in the surface of a polished copper interconnect.

U.S. Pat. No. 6,368,194 B1 (Sharples et al.) shows an apparatus for controlling pH during chemical-mechanical polish (CMP).

U.S. Pat. No. 6,354,913 (Miyashita et al.) reveals a pH controller for a copper chemical-mechanical polish (CMP) tool.

U.S. Pat. No. 5,972,792 (Hudson) shows another pH control for copper chemical-mechanical polish (CMP).

U.S. Pat. No. 6,261,158 B1 (Holland et al.) is a related patent.

### SUMMARY OF THE INVENTION

A principle objective of the invention is to provide a method of polishing copper surfaces whereby the polished copper surface is free of surface defects.

Another objective of the invention is to provide a method of polishing copper surfaces whereby the polished copper surface does not contribute to concerns of device reliability.

Yet another objective of the invention is to provide a method of polishing copper surfaces whereby the polished copper surface does not decrease device performance due to increased interconnect resistance.

In accordance with the objectives of the invention a new method is provided for polishing, using methods of Chemical Mechanical Polishing, of copper surfaces, particularly where these surface are adjacent to the surface of a layer of barrier material comprising TaN. The invention provides for reducing the chemical force early in the polishing process by adding DIW during the early polishing phase and for additional control of the chemical force during the polishing process by controlling the pH of the slurry applied during polishing, especially for polishing the interface between interconnect copper and barrier material TaN.

### BRIEF DESCRIPTION OF THE DRAWINGS

FIG. 1 shows a prior art Chemical Mechanical Polishing arrangement.

FIGS. 2a and 2b show prior art CMP processing steps and their results.

FIGS. 3a and 3b show cross sections of copper CMP improvements with FIG. 3a showing a cross section of conventionally obtained results while FIG. 3b shows a cross section of results obtained by the invention.

FIG. 4 shows a graph of the nominal force that is applied to a surface that is being polished as a function of time, distinguishing between chemical and mechanical force.

FIG. 5 shows the variation of applied pH factor as a function of polishing time.

FIG. 6 shows a sequence of the successive steps of polishing a wafer, specifically highlighting the various layers that are being substantially polished.

FIG. 7 shows the apparatus of the invention used for controlling a pH factor during polishing of a copper surface.

### DESCRIPTION OF THE PREFERRED EMBODIMENTS

FIG. 1 shows a Prior Art CMP apparatus. A polishing pad 20 is affixed to a circular polishing table 22 that rotates in a direction indicated by arrow 24 at a rate in the order of 1 to 100 RPM. A wafer carrier 26 is used to hold wafer 18 face down against the polishing pad 20. The wafer 18 is held in place by applying a vacuum to the backside of the wafer (not shown). The wafer 18 can also be attached to the wafer carrier 26 by the application of a substrate attachment film (not shown) to the lower surface of the wafer carrier 26. The wafer carrier 26 also rotates as indicated by arrow 32, usually in the same direction as the, polishing table 22, at a rate on the order of 1 to 100 RPM. Due to the rotation of the polishing table 22, the wafer 18 traverses a circular polishing path over the polishing pad 20. A force 28 is also applied in the downward vertical direction against wafer 18 and presses the wafer 18 against the polishing pad 20 as it is being polished. The force 28 is typically in the order of 0 to 15 pounds per square inch and is applied by means of a shaft 30 that is attached to the back of wafer carrier 26.

A typical CMP process involves the use of a polishing pad made from a synthetic fabric and a polishing slurry, which includes pH-balanced chemicals, such as sodium hydroxide, and silicon dioxide particles.

Abrasive interaction between the wafer and the polishing pad is created by the motion of the wafer against the polishing pad. The pH of the polishing slurry controls the chemical reactions, e.g. the oxidation of the chemicals that comprise an insulating layer of the wafer. The size of the silicon dioxide particles controls the physical abrasion of surface of the wafer.

The polishing pad is typically fabricated from a polyurethane (such as non-fibrous polyurethane, cellular polyurethane or molded polyurethane) and/or a polyester based material. Pads can for instance be specified as being made of a microporous blown polyurethane material having a planar surface and a Shore D hardness of greater than 35 (a hard pad).

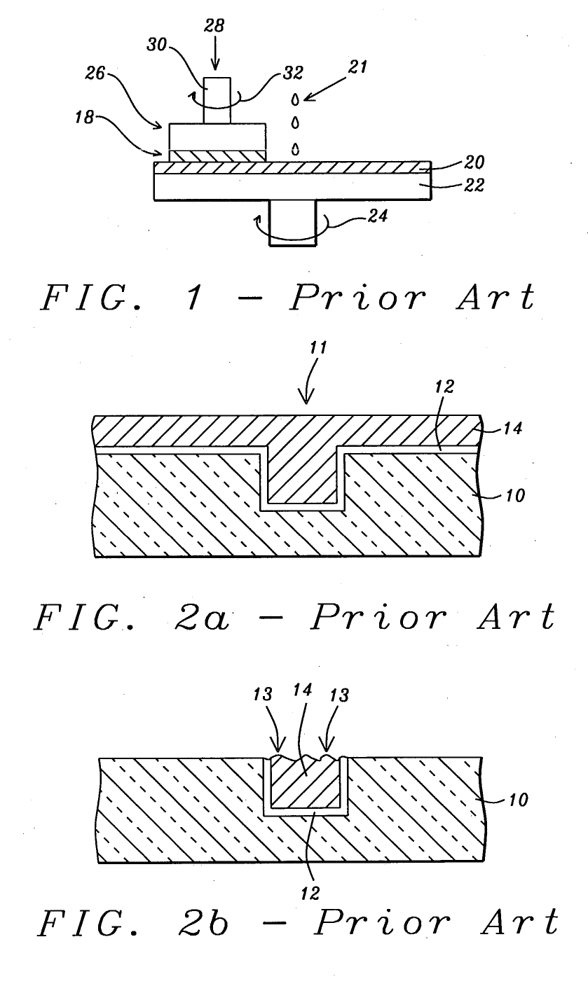

A number of observations will first be highlighted relating to the occurrence of copper surface recesses, FIG. 2a through 2b will be used for this. A recess is thereby defined as any deviation of a copper surface from an ideal or totally flat (or planarized) copper surface. These observations can be summarized as follows and are based on empirical observations of polished copper surface:

1. The severity of recesses is higher in higher levels of metals as opposed to lower levels of metal; that is the occurrence of recesses is for instance more severe in level 6 metal (M6) than in level 3 metal (M3)

2. The recesses are dependent of the length of a copper interconnect line to which an overlying via interconnect is attached; the longer the interconnect line the more severe the recess in the surface of the polished via, and

3. The recesses are dependent on the size of the surface that is being polished; a small surface area has more recesses than a larger surface area.

For an explanation of the above highlighted observations the following is suggested:

1. Higher level of copper are created in overlying layers of dielectric and are therefore less firmly anchored or supported than the lower levels of metal, causing increased likelihood of vibration of the higher levels of copper

2. A shorter interconnect line to which an overlying copper via is attached is a firmer body of metal than a longer interconnect line. The longer interconnect line is therefore more prone to vibrate, a vibration that is transferred to the thereto connected via resulting in unstable contact between the polishing pad and the surface of the via at the time of polishing of the surface of the via, and

3. A larger surface area will more uniformly contact a polishing pad than a smaller surface area, resulting in more uniform polishing of the larger surface area and therefore of fewer recesses created in the surface thereof.

The above highlighted observations must be interpreted while remembering that the interaction of a surrounding layer of barrier material of TaN with the surface of the copper interconnect that is being polished has been identified as being the root cause of the occurrence of recesses. This interaction is additionally and dependently stimulated in accordance with the conditions of design and polishing that have been highlighted above.

Surface recesses are highlighted using FIGS. 2a and 2b for this purpose, from which it will be clear that any deviation from a planar copper surface after polishing thereof is identified as a recess of this surface. Specifically highlighted in the cross sections of FIGS. 2a and 2b is a layer 10 of dielectric that is used to create a pattern of copper interconnect therein or there over. Opening 11 has for this purpose been created in the surface of layer 10, a barrier layer 12 has been deposited over the surface of which a layer 14 of copper has been deposited. The surface of copper layer 14 is then polished, removing the copper and the underlying layer 12 of barrier material from the surface of layer 10 of dielectric as shown in the cross section of FIG. 2b. It is clear from this cross section that, in proceeding from the cross section of FIG. 2a to the cross section of FIG. 2b, the copper of layer 14 and the TaN of layer 12 have considerable opportunity to interact, an interaction that causes the recesses 13 in the surface of the polished copper layer 14, FIG. 2b.

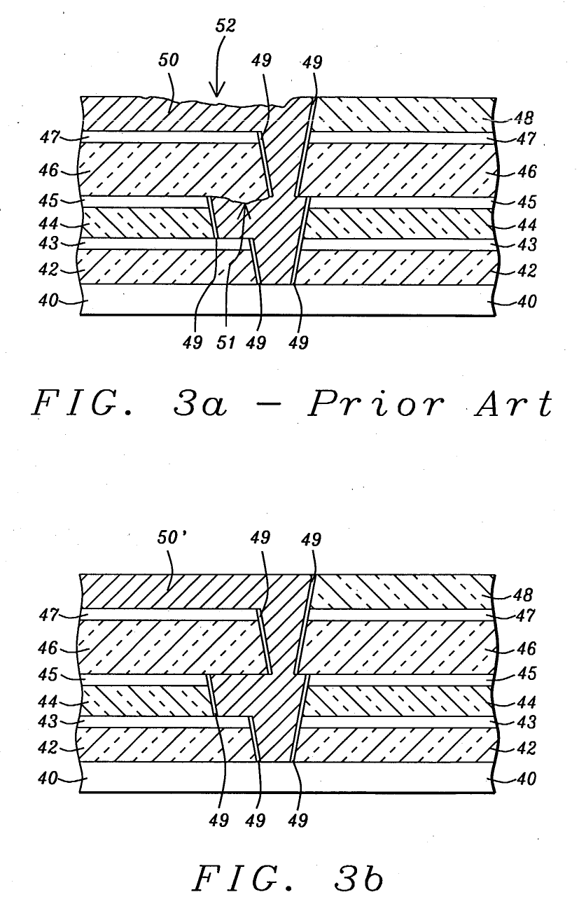

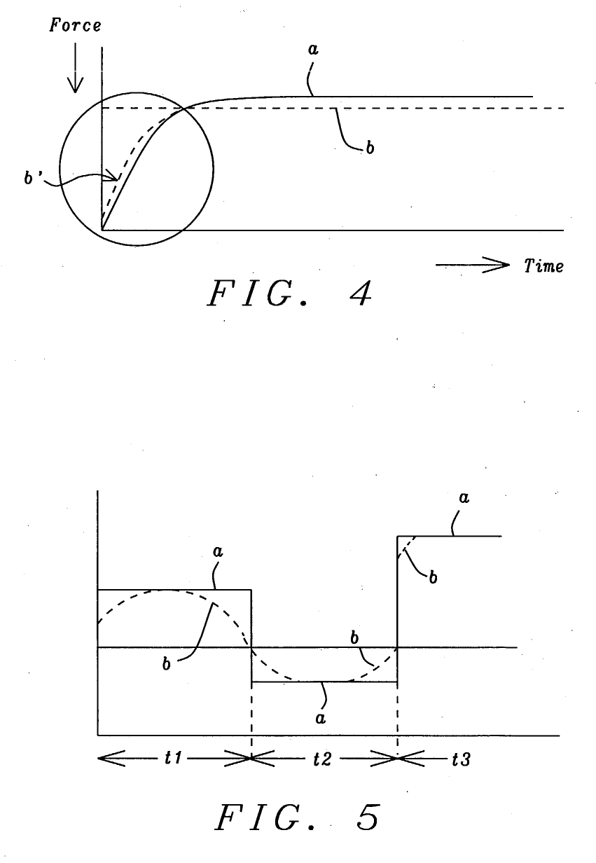

The improvements that are achieved by the invention are highlighted using FIGS. 3a and 3b, wherein FIG. 3a shows a conventionally created compound copper interconnect comprising:

40, a semiconductor surface, typically the surface of a monocrystalline silicon substrate

42, 44, 46 and 48 are respectively first, second, third and fourth layers of dielectric

43, 45, and 47 are respectively first, second and third layers of etch stop material

49, is a layer of barrier material, preferably comprising TaN, surrounding the created copper interconnect

50, is the composite copper interconnect that has been created through openings created through the highlighted layers of dielectric and etch stop material.

A first recess 51 is hiqhliqhted in the cross section of FIG. 3a, this recess causes a void in the overlying layer 46 of dielectric, leading to concerns of device reliability in addition to concerns of device performance. A second recess 52 is shown in the upper layer of metal 50, this recess 52 is more extensive than recess 51 for reasons that previously have been highlighted.

The cross section that is shown in FIG. 3b shows the same interconnect configuration as has been shown in the cross section of FIG. 3a, it is however clear from the cross section that is shown in FIG. 3b that all contours of the created interconnect metal 50′ are as desired and are not negatively impacted by recesses as they have been highlighted in the cross section of FIG. 3a. The cross section of the interconnect metal 50′ that is shown in FIG. 3b approaches an ideal layer of overlying interconnect metal, extended over several overlying layers of metal that are interconnected by vias.

It must relative to the cross sections that are shown in FIGS. 3a and 3b be pointed out that these cross sections as shown represent pictorial observations of actual cross sections that have been obtained using prior art technology (FIG. 3a) and using the invention (FIG. 3b). These cross sections are therefore representative of empirical results relating to the invention.

The occurrence of recesses has been explained with the following relationship: Cu→Cu²⁺+2e⁻, indicating that polishing of a copper surface removes two electrons from the copper molecules, these electrons are believed to be attracted by and to be absorbed by the barrier material of TaN. This is believed to bias the TaN to additionally interact with the copper molecules that are removed by polishing.

Further, copper ions that are removed by polishing can be redeposited over the surface of adjacent copper, further aggravating the creation of recesses over the polished copper surfaces.

During a process of CMP two forces are in effect: a mechanical force and a chemical force. The mechanical force is created by all factors of influence that affect the friction between the polishing pad and the surface that is being polished. One of these forces is force 28, highlighted in FIG. 1. Other forces that have the same affect of controlling the friction between the polishing pad and the surface that is being polished can be provided such as type and polishing rate (removal rate) of the polishing pad.

The chemical force is the impact on the polishing action that is provided by chemical interaction with the surface that is being polished. This chemical interaction is therefore most significantly controlled and determined by the slurry and the pH factor of the slurry that is applied to the surface that is being polished.

FIG. 4 shows a graph of the mechanical and chemical forces as these forces apply during the time that the polishing process is performed. Curve “a”, FIG. 4, represents the mechanical force as a function of polishing time, curve “b”, FIG. 4, represents the chemical force as a function of polishing time. From the graph it is clear that initially, that is at the start of the polishing process, the chemical force (curve “b”) exceeds the mechanical force (curve “a”).

From FIG. 4 it is clear that, during the initial phase of the polishing action, the mechanical force and the chemical force can be balanced by following curve “b′” of FIG. 4, that is by lowering the chemical force during the initial stages of the polishing process.

From the previously highlighted cross section of FIG. 2a, it is clear that the sequence of polishing is as follows:

1. Copper (14, FIG. 2a) polishing

2. TaN (12, FIG. 2a) polishing

3. Dielectric (10, FIG. 2b) polishing.

In the graph shown in FIG. 5 the time of polishing is plotted along the horizontal or X-axis. The pH factor of the slurry (influencing the chemical force or removal rate contributed by the slurry) is plotted along the vertical or Y-axis. The parameters that are of importance along the X-axis are t1, which is the time during which copper polishing is performed, t2, which is the time during which TaN polishing is performed and t3, which is the time during which dielectric polishing is performed.

The conventional control of the pH factor during these phases of polishing is represented by curve “a”, which comprises step functions of pH control. From this it is clear that the chemical force or the removal rate that is controlled by chemical influences can be controlled by for instance assuring that the pH during polishing of all three surfaces follows curve “b” of FIG. 5. Curve “b”, FIG. 5, initially is lower than the conventional pH curve “a”, curve “b” drops after the pH value has reached the pH value of curve “a” during polishing of a copper surface.

It is clear that the chemical force, which is proportional to the pH of the slurry, can be controlled by rounding off the rectangular nature of curve “a”, FIG. 5, in interfaces of:

the transition of polishing the copper layer to the TaN layer, that is the transition from t1 to t2, and

the transition of polishing the TaN layer to polishing the dielectric layer, that is the transition from t2 to t3,

From this follows a final step of the invention. The successive polishing of the three layers of respectively copper, TaN and dielectric is performed by feeding the wafer that is to be polished into a polishing apparatus. The wafer is held in a rotating polishing platen, the rotation of the platen advances the wafer from a copper polishing location to a TaN polishing location to a dielectric polishing location. By therefore linking the slurry supply and the pH factor of the slurry with the position of the wafer within the polishing apparatus, the pH factor of the slurry can be controlled in accordance with the polishing operation to which the wafer is subjected at any given time.

From this can be realized controlling the pH factor, FIG. 5, in accordance with time t1, t2 and t3, that is with the surface that is being polished.

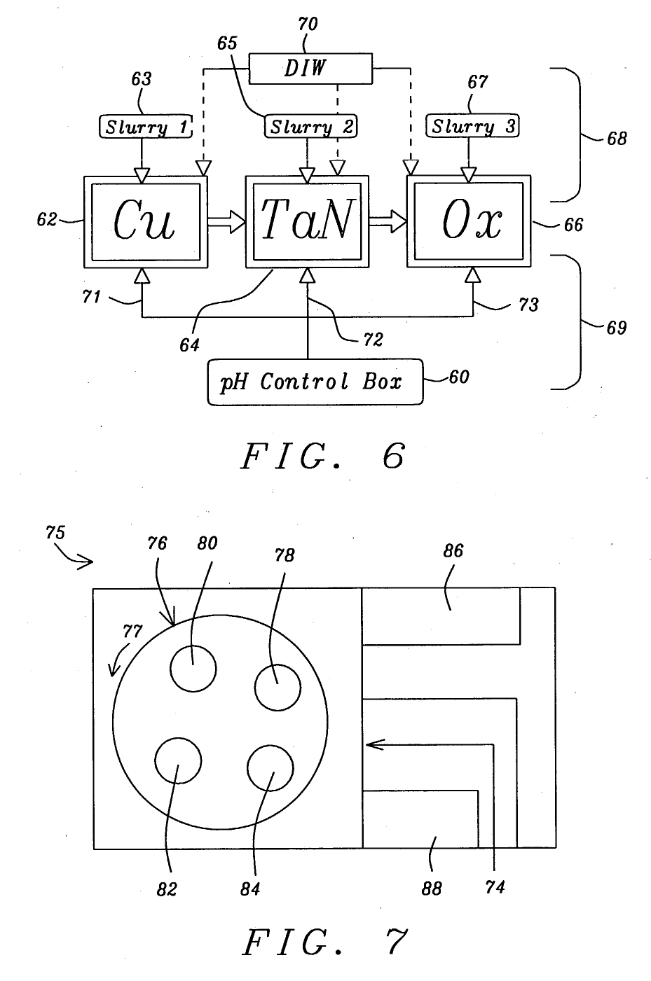

The implementation of this concept is shown in FIG. 6, where pH control box 60 is provided for the control of the pH factor of the slurry that is provided over the surface that is being polished. These surfaces are highlighted as:

surface 62 of copper, during the polishing of which slurry 1 (element 63) is provided adjusted by pH control box 60 for a desired pH factor

surface 64 of TaN, during the polishing of which slurry 2 (element 65) is provided adjusted by pH control box 60 for a desired pH factor, and

surface 66 of dielectric (oxide or a compound thereof), during the polishing of which slurry 3 (element 67) is provided adjusted by pH control box 60 for a desired pH factor.

DIW can be provided using DIW supply vessel 70 for this purpose. DIW can be supplied at initiation of the polishing process and can be extended over a time period into the polishing process, for instance a time period equal to between about 0 and 40% of the time that is required to complete the polishing process. The time that is required to complete the polishing process comprises the time that is required for polishing of the layer of copper, the layer of barrier material and optionally further extending into the underlying layer of dielectric.

In the presentation that is shown in FIG. 6, the collective elements 68 will be recognized as prior art components of an arrangement for the polishing of copper surfaces that are created in a layer of dielectric and that are surrounded by a layer of barrier material, collective elements 69 will be recognized as the invention the addition by of the pH control box 60 to the conventional elements 68.

Interfaces 71, 72 and 73 form the interfaces between the pH control box 60 and respectively:

71, the pH constant of slurry 1 that is applied for the polishing of the copper surface 62,

72, the pH constant of slurry 2 that is applied for the polishing of the TaN barrier layer 64,

73, the pH constant of slurry 3 that is applied for the polishing of the dielectric (oxide) surface 66.

The implementation or apparatus of the invention can performed as shown in FIG. 7, wherein:

75 is the overall apparatus of the invention

74 is the path along which the wafer that is to be polished is entered into the apparatus 75 of the invention

76 is the rotating platen of the apparatus of the invention, which contains the wafer that is to be polished in a rotating capacity, placing the wafer into desired polishing positions

77 is the direction of rotation of the rotational platen 76

78 is the initial station after the wafer has been entered into the rotating platen of the apparatus 75; this position can be used to provide initial positioning and positioning verification capabilities and therewith related data access requirements

80 is the copper polishing position

82 is the barrier layer, preferably comprising TaN, polishing position,

84 is the dielectric, preferably comprising oxide or a compound thereof, polishing position

86 is the post-clean position, and

88 is the location of the pH control box.

To summarize the invention: the invention provides for the control of the pH factor of the slurry and therewith for the control of the chemical factor of material removal during the polishing of successive layers of material.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method to polish metal surfaces, comprising:
providing a substrate, a patterned layer of metal having been provided over the surface thereof; and
controlling a polishing rate when polishing the surface of the layer of metal by controlling a pH factor of a slurry applied during the polishing.

2. The method of claim 1, the metal comprising copper.

3. The method of claim 1, the polishing the surface of the layer of metal comprising methods of Chemical Mechanical Polishing (CMP).

4. The method of claim 1, the controlling a polishing rate comprising controlling a polishing rate as a function of polishing time.

5. The method of claim 1, the controlling a pH factor of a slurry comprising controlling a pH factor of a slurry as a function of polishing time.

6. The method of claim 5, the controlling a pH factor of a slurry as a function of polishing time comprising a pH Control Box.

7. The method of claim 1, additionally supplying DI water at initiation and from there extending over a time period of the polishing the surface of the layer of metal.

8. The method of claim 1, the patterned layer of metal being at least partially bounded by a layer of barrier material.

9. The method of claim 8, the barrier material comprising TaN.

10. The method of claim 8, the layer of barrier material being at least partially bounded by a layer of dielectric.

11. The method of claim 10, the dielectric comprising oxide or a compound thereof.

12. A method to polish copper surfaces, comprising:
providing a substrate, a patterned layer of copper having been provided over the surface thereof; and
controlling a polishing rate when polishing the surface of the patterned layer of copper by controlling a pH factor of a slurry applied during the polishing.

13. The method of claim 12, the polishing the surface of the patterned layer of copper comprising methods of Chemical Mechanical Polishing (CMP).

14. The method of claim 12, the controlling a polishing rate comprising controlling a polishing rate as a function of polishing time.

15. The method of claim 12, the controlling a pH factor of a slurry comprising controlling a pH factor of a slurry as a function of polishing time.

16. The method of claim 15, the controlling a pH factor of a slurry as a function of polishing time comprising a pH Control Box.

17. The method of claim 12, additionally supplying DI water at initiation and from there extending over a time period of the polishing the surface of the layer of copper.

18. The method of claim 12, the patterned layer of copper being at least partially bounded by a layer of barrier material.

19. The method of claim 18, the barrier material comprising TaN.

20. The method of claim 18, the layer of barrier material being at least partially bounded by a layer of dielectric.

21. A method to polish metal surfaces, comprising:
providing a substrate, a patterned layer of copper having been provided over the surface thereof, the patterned layer of copper being at least partially bounded by a layer of barrier material, the layer of barrier material being at least partially bounded by a layer of dielectric; and
controlling a polishing rate when polishing the surface of the patterned layer of copper, thereby polishing the bounding layer of barrier material, thereby polishing the bounding layer of dielectric, by controlling a pH factor of a slurry applied during the polishing.

22. The method of claim 21, the controlling a polishing rate comprising controlling a polishing rate as a function of polishing time.

23. The method of claim 21, the controlling a pH factor of a slurry comprising controlling a pH factor of a slurry as a function of polishing time.

24. The method of claim 23, the controlling a pH factor of a slurry as a function of polishing time comprising a pH Control Box.

25. The method of claim 21, the barrier material comprising TaN.

26. The method of claim 21, additionally supplying DI water at initiation and from there extending over a time period of the polishing the surface of the patterned layer of copper.

27. A method to polish metal surfaces, comprising:
providing a substrate, a patterned layer of copper having been provided over the surface thereof, the patterned layer of copper being at least partially bounded by a layer of barrier material, the layer of barrier material being at least partially bounded by a layer of dielectric; and
controlling a polishing rate when polishing the surface of the patterned layer of copper by applying methods of Chemical Mechanical Polishing (CMP), thereby polishing the bounding layer of barrier material, thereby polishing the bounding layer of dielectric, by controlling a pH factor of a slurry applied during the polishing.

28. The method of claim 27, the controlling a polishing rate comprising controlling a polishing rate as a function of polishing time.

29. The method of claim 27, the controlling a pH factor of a slurry comprising controlling a pH factor of a slurry as a function of polishing time.

30. The method of claim 28, the controlling a pH factor of a slurry as a function of polishing time comprising a pH Control Box.

31. The method of claim 27, additionally supplying DI water at initiation and from there extending over a time period of the polishing the surface of the patterned layer of copper.

32. The method of claim 27, the barrier material comprising TaN.

33. A method to polish metal surfaces, comprising:
providing a substrate, a patterned layer of copper having been provided over the surface thereof, the patterned layer of copper being at least partially bounded by a layer of barrier material, the layer of barrier material being at least partially bounded by a layer of dielectric; and
controlling a polishing rate as a function of polishing time when polishing the surface of the patterned layer of copper by applying methods of Chemical Mechanical Polishing (CMP), thereby polishing the bounding layer of barrier material, thereby polishing the bounding layer of dielectric, by controlling a pH factor of a slurry applied during the polishing.

34. A method to polish metal surfaces, comprising:
providing a substrate, a patterned layer of copper having been provided over the surface thereof, the patterned layer of copper being at least partially bounded by a layer of barrier material, the layer of barrier material being at least partially bounded by a layer of dielectric; and
controlling a polishing rate as a function of polishing time when polishing the surface of the patterned layer of copper by applying methods of Chemical Mechanical Polishing (CMP), thereby polishing the bounding layer of barrier material, thereby polishing the bounding layer of dielectric, by controlling a pH factor of a slurry applied during the polishing as a function of polishing time.

35. A method to polish metal surfaces, comprising:
providing a substrate, a patterned layer of copper having been provided over the surface thereof, the patterned layer of copper being at least partially bounded by a layer of barrier material, the layer of barrier material being at least partially bounded by a layer of dielectric;
supplying DI water at initiation and from there extending over a time period of polishing the surface of the patterned layer of copper; and
controlling a polishing rate as a function of polishing time when polishing the surface of the patterned layer of copper by applying methods of Chemical Mechanical Polishing (CMP), thereby polishing the bounding layer of barrier material, thereby polishing the bounding layer of dielectric, by controlling a pH factor of a slurry applied during the polishing as a function of polishing time.

36. A method to polish metal surfaces, comprising:
providing a substrate;
depositing a layer of dielectric over the surface of the substrate;
patterning and etching the layer of dielectric, creating at least one opening in the surface of the layer of dielectric;
depositing a layer of barrier material over the surface of the layer of dielectric, including inside surfaces of the at least one opening created in the layer of dielectric;
depositing a layer of metal over the surface of the layer of barrier material; and
controlling a polishing rate in a polishing time dependent manner when successively polishing the surface of the layer of metal, the layer of barrier material and the layer of dielectric by controlling a pH factor of a slurry applied during the polishing.

37. An apparatus for polishing metal surfaces, comprising:
a rotating wafer carrier, the rotating wafer carrier having been provided with means for positioning a wafer in stations of the apparatus;
means for entering a wafer into the apparatus;
means for entering the wafer into the rotating wafer carrier;
a first station for positioning a wafer by the rotating wafer carrier;
at least one second station for polishing a layer of semiconductor material, the wafer being position in the at least one second station by the rotating wafer carrier;
at least one slurry supply;
means for applying the at least one slurry supply to the at least one second station for polishing a layer of semiconductor material; and
means for controlling a pH factor of the at least one slurry supply.

38. The apparatus of claim 37, the layer of semiconductor material being selected from the group consisting of metal and barrier material and dielectric.

39. The apparatus of claim 37, additionally comprising means for DI water supply.

40. The apparatus of claim 37, the means for controlling a pH factor of the at least one slurry comprising a pH control box.

41. The apparatus of claim 37, the at least one second station for polishing a layer of semiconductor material being selected from the group consisting of a metal polishing station and a barrier material polishing station and a dielectric polishing station.
